(19) United States
(12) Patent Application Publication
(10) Pub. No.: US 2006/0148205 A1
(43) Pub. Date: Jul. 6, 2006

(54) Semiconductor manufacturing method for device isolation

(76) Inventors: Yoshikazu Akiba, Hitachinaka (JP); Hisaharu Sawai, Hitachinaka (JP); Katsuhiko Hotta, Hachioji (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/324,512

(22) Filed: Jan. 4, 2006

(30) Foreign Application Priority Data
Jan. 5, 2005 (JP) 2005-000943

(51) Int. Cl. H01L 21/76; H01L 21/461

(52) U.S. Cl. 438/424; 438/692

(57) ABSTRACT

Provided is a manufacturing step of an element isolation by forming an isolation trench in an element isolation region of a semiconductor substrate, forming an HDP film over the semiconductor substrate including the inside of the isolation trench, and then polishing the HDP film by CMP to remove the HDP film outside the isolation trench, wherein the HDP film is formed at a sputter etching/deposition ratio ranging from 0.12 to 0.22 to relatively decrease the height of the protrusions of the HDP film, and after polishing of the protrusions of the HDP film by an additive-containing ceria-based slurry, the remaining HDP film outside the isolation trench is removed successively by using the additive-containing ceria-based slurry diluted with deionized water fed onto the semiconductor substrate. In a manufacturing step of an element isolation by forming an isolation trench in an element isolation region of a semiconductor substrate, forming an HDP film over the semiconductor substrate including the inside of the isolation trench, and then polishing the HDP film by CMP to remove the HDP film outside the isolation trench, the HDP film is formed at a sputter etching/deposition ratio ranging from 0.12 to 0.22 to relatively decrease the height of the protrusions of the HDP film, and after polishing of the protrusions of the HDP film by an additive-containing ceria-based slurry, the remaining HDP film outside the isolation trench is removed successively by using the additive-containing ceria-based slurry diluted with deionized water fed onto the semiconductor substrate. The present invention makes it possible to reduce the polishing time of an HDP film in a CMP step.

### CROSS-REFERENCE TO RELATED APPLICATION

The present application claims priority from Japanese patent application No. 2005-000943 filed on Jan. 5, 2005, the content of which is hereby incorporated by reference into this application.

### BACKGROUND OF THE INVENTION

The present invention relates to a manufacturing technology of a semiconductor device, particularly to a technology effective when applied to the manufacture of a semiconductor device by filling a recess formed on the semiconductor substrate of the device with an insulating film followed by CMP process.

For example, Japanese Unexamined Patent Publication No. 2004-179571 describes a technology of making the trench isolation, in a step of depositing an insulating film to fill a trench, the insulating film is deposited sufficiently thicker than a trench depth to reduce the height or inclination of protrusions on the surface of the insulating film, thereby suppressing the generation of broken protrusion pieces in the CMP step which will otherwise occur by the breakage of the insulating film at the protrusions.

In addition, Japanese Unexamined Patent Publication No. 2004-47676 describes a technology of forming a trench in a semiconductor substrate, forming a high-density plasma oxide film so that the film thickness becomes about 103 to 117% of the depth of the trench, polishing the high-density plasma oxide film with a ceria-based slurry until self stopping of the polishing, and successively polishing the remaining high density plasma oxide film with a slurry diluted with water.

In addition, Japanese Unexamined Patent Publication No. 2004-228519 describes a technology of forming, over a high density plasma oxide film, a film having an equal level of polishing rate to that of the high density plasma oxide film in order to reinforce protrusions in the form of a triangular prism or triangular pyramid and then carrying out CMP polishing with a ceria-based slurry.

In addition, Japanese Unexamined Patent Publication No. 2003-318140 discloses a polishing method of an oxide film formed over a substrate having a recess therein which method is composed of four steps, that is, a first step of flattening the oxide film with a self-stop type abrasive, a second step of polishing the oxide film with an a self-stop type abrasive added with water or a high selectivity type abrasive while maintaining the flatness of the oxide film, a third step of polishing the oxide film further with the self-stop type abrasive added with water or the high selectivity type abrasive while exposing a portion of a protection film below the oxide film, and a fourth step of polishing the oxide film further while exposing the protection film substantially completely.

In addition, Japanese Unexamined Patent Publication No. 2002-299332 discloses a plasma film formation method comprising forming a first oxide film to cover elements over a substrate without applying a bias to electrodes, forming a second oxide film to be filled in minute spaces between the elements or interconnects by applying a bias to electrodes, and then forming a third oxide film at a high speed without applying a bias to electrodes.

### SUMMARY OF THE INVENTION

Shallow trench isolation obtained by filling an insulating material inside of a trench of from about 200 nm to 400 nm deep is employed as a method of electrically isolating two adjacent semiconductor elements. Compared with LOCOS (Local Oxidation of Silicon) isolation which is typical element isolation, the shallow trench isolation can realize higher flatness and narrower element isolation region. Owing to such advantages, it is used popularly for the manufacture of semiconductor devices on and after the 0.18 μm process generation.

The manufacture of the above-described shallow trench isolation however has various technical problems which will be described below.

The shallow trench isolation is formed by making a trench in an element isolation region of a semiconductor substrate, forming a film of an insulating material over the semiconductor substrate including the inside of the trench, and polishing the insulating material by chemical mechanical polishing (CMP) to remove the insulating material outside the trench. The insulating material has, formed therebelow, a protection film serving to stop the insulating material polishing.

As the insulating material, a silicon oxide film (which will hereinafter be called “HDP film”) having excellent filling property and formed by high density plasma CVD (High Density Plasma Chemical Vapor Deposition) is used. This high density plasma CVD is a technology of filling a step difference of the uneven portion while carrying out CVD and sputtering process simultaneously. When this technology is employed for the manufacture of element isolation, conditions upon formation of the HDP film or thickness of the deposited film is determined mainly based on the filling property inside of the trench. The HDP film formed over the semiconductor substrate therefore has a characteristic deposited film form, more specifically, has protrusions in the form of a trapezoid, a triangular roof or triangular pyramid (which will hereinafter be called “protrusions” simply) on the upper surface outside (convex portion) the trench. The form of the protrusions of the HDP film varies easily depending on the dense/or coarse integration degree of trenches or their aspect ratio. For example, as the trenches are made at a higher density, the protrusions tend to be larger. It is therefore presumed that narrowing tendency of the element isolation in future owing to high integration will result in an increase in the size of the protrusions of the HDP film.

As a result of the investigation by the present inventors, it has been elucidated that the polishing time of the HDP film in the CMP step greatly depends on the shape of the protrusions of the HDP film and as the protrusions of the HDP film become larger, the polishing time of the HDP film becomes longer. This is presumed to occur because larger protrusions facilitate remaining of a polishing slurry in a recess and disturb efficient action of an abrasive grain to function for protrusions polishing. An increase in the polishing time of the HDP film leads to extension of a turn around time (TAT) of a semiconductor device manufacture adopting shallow trench isolation so that shortening of the polishing time of the HDP film in the CMP step is one of main themes in the semiconductor device manufacture adopting shallow trench isolation.

In recent years, an additive-containing ceria (CeO)-based slurry has been employed as a slurry for CMP because it has a higher polishing rate selectivity (ratio of a polishing rate of a material to be polished relative to a polishing rate of a protection film) than silica (SiO)-based slurry and permits selective polishing of a convex portion. The additive-containing ceria-based slurry is a self-stop type abrasive and it is prepared mainly for selectively polishing the convex portion on a surface to be polished, thereby removing the unevenness on the surface. When the additive-containing ceria-based slurry is used, the polishing rate automatically slows down as the unevenness on the surface is eliminated. At last, the polishing of the surface substantially stops while leaving only the material to be polished.

For the formation of a shallow trench isolation, complete removal of the HDP film on the protection film is necessary. After the unevenness of the HDP film is eliminated, polishing of the HDP film with a ceria-based slurry different from the above-described one in the concentration or kind of the additive is continued until the protection film is exposed.

An additive concentration regulator, a plurality of slurry supply line systems or a plurality of polishing apparatuses become necessary in order to change the concentration or kind of the additive of the ceria-based slurry. It however increases the equipment investment and in addition, makes it difficult to successively carry out polishing for eliminating the unevenness of the HDP film and polishing of the HDP film until exposure of the protection film. A change in the concentration or kind of the additive of the ceria-based slurry therefore results in deterioration of a polishing efficiency.

An object of the present invention is therefore to provide a technology capable of shortening the polishing time of the HDP film in the CMP step.

The above-described and the other objects and novel features of the present invention will be apparent from the description herein and accompanying drawings.

Of the inventions disclosed by the present application, a typical one will next be summarized below.

A manufacturing method of a semiconductor device according to the present invention has a step of forming a trench in an element isolation region of a semiconductor substrate, a forming an HDP film on the semiconductor substrate including the inside of the trench, and polishing the HDP film by CMP to remove a portion of the HDP film outside the trench, thereby forming an element isolation. By forming the HDP film while adjusting a ratio of the thickness of a film to be sputtered to the thickness of a film to be deposited (simply a ration of sputtering ratio to depositing ratio) to fall within a range of from 0.12 to 0.22, the protrusions of the HDP film are made relatively thinner and a polishing time of the HDP film is shortened. In addition, a polishing efficiency of the HDP film is improved by polishing the protrusions of the HDP film with an additive-containing ceria-based slurry, diluting the additive-containing ceria-based slurry with deionized water fed onto the semiconductor substrate, and polishing a remaining portion of the HDP film outside the trench with the additive-containing ceria-based slurry thus diluted.

Of the inventions disclosed by the present application, advantages available by the typical one will next be described briefly.

A polishing time of an HDP film in a CMP step can be shortened.

### BRIEF DESCRIPTION OF THE DRAWINGS

FIG. 1 is a fragmentary cross-sectional view of a semiconductor substrate illustrating the manufacturing step of shallow trench isolation according to one embodiment of the present invention;

FIG. 2 is a fragmentary cross-sectional view illustrating a portion similar to that in FIG. 1 in a manufacturing step following that of FIG. 1;

FIG. 3 is a fragmentary cross-sectional view illustrating a portion similar to that in FIG. 1 in a manufacturing step following that of FIG. 2;

FIG. 4 illustrates one example of a schematic view of a high density plasma CVD apparatus;

FIG. 5 illustrates one example of a schematic view of a CMP apparatus;

FIG. 6 is a fragmentary cross-sectional view illustrating a portion similar to that in FIG. 1 in a manufacturing step following that of FIG. 3;

FIG. 7 is a graph showing one example of the relationship between the driving motor torque current of a polishing pad and polishing time;

FIG. 8 is a fragmentary cross-sectional view illustrating a portion similar to that in FIG. 1 in a manufacturing step following that of FIG. 6; and

FIG. 9 is a graph showing one example of the relationship between the driving motor torque current of a polishing pad and polishing time.

### DETAILED DESCRIPTION OF THE INVENTION

In the below-described embodiment, a description will be made after divided in plural sections or in plural embodiments if necessary for convenience's sake. These plural sections or embodiments are not independent each other, but in a relation such that one is a modification example, details or complementary description of a part or whole of the other one unless otherwise specifically indicated.

In the below-described embodiments, when a reference is made to the number of elements (including the number, value, amount and range), the number is not limited to a specific number but can be greater than or less than the specific number unless otherwise specifically indicated or principally apparent that the number is limited to the specific number. Moreover in the below-described embodiments, it is needless to say that the constituting elements (including element steps) are not always essential unless otherwise specifically indicated or principally apparent that they are essential. Similarly, in the below-described embodiments, when a reference is made to the shape or positional relationship of the constituting elements, that substantially analogous or similar to it is also embraced unless otherwise specifically indicated or principally apparent that it is not. This also applies to the above-described value and range.

In the below-described embodiments, the term “wafer” indicates mainly “Si (Silicon) single crystal wafer”, but the term “wafer” indicates not only it but also SOI (Silicon On Insulator) wafer or an insulating film substrate for forming an integrated circuit thereover. The shape of the wafer is not limited to disc or substantially disc, but also square and rectangular wafer can be employed.

In all the drawings for describing the embodiments, like members of a function will be identified by like reference numerals and overlapping descriptions will be omitted. The present invention will hereinafter be described in detail based on accompanying drawings.

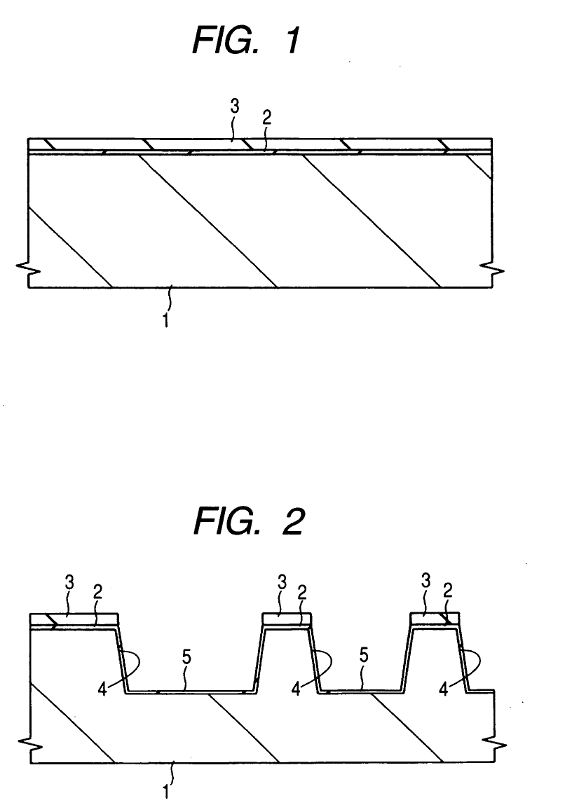

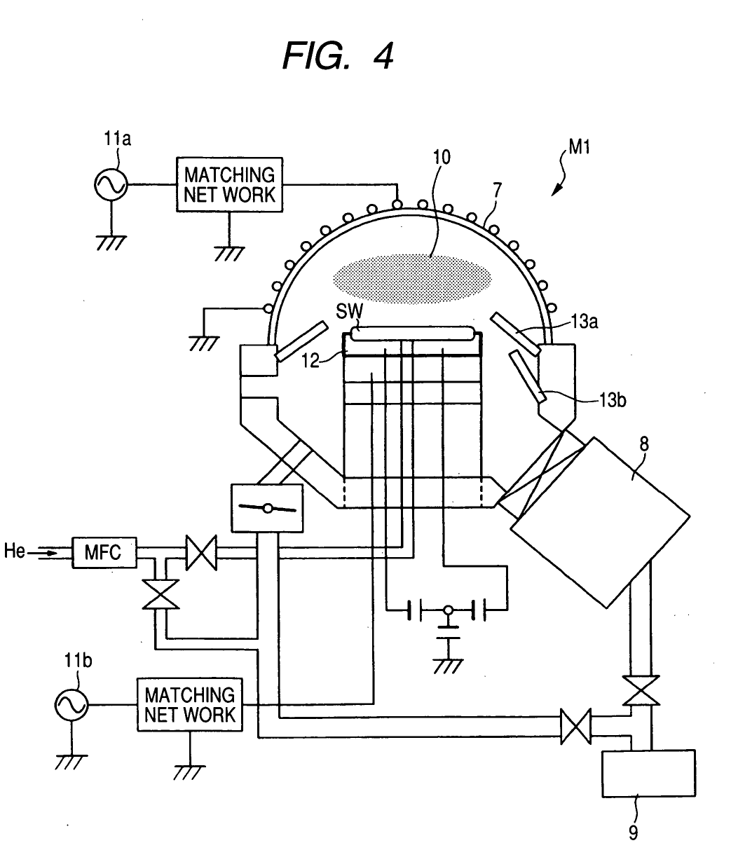

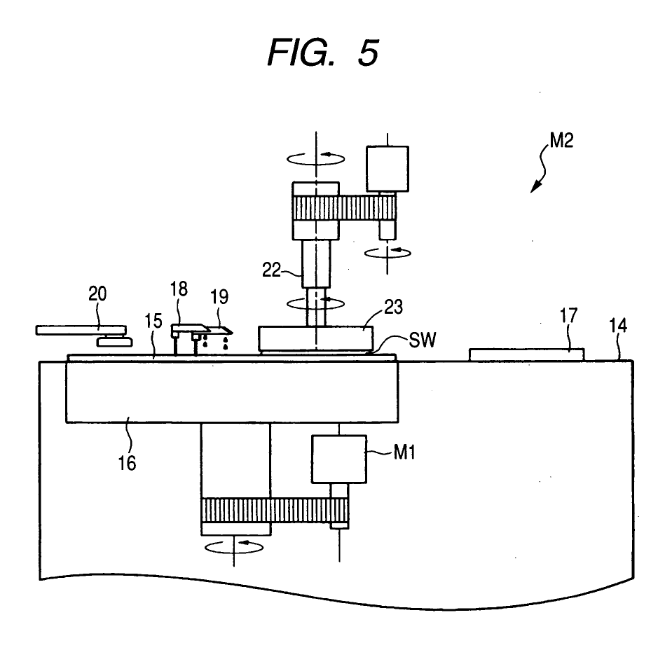

Referring to FIGS. 1 to 8, a manufacturing method of shallow trench isolation according to one embodiment of the present invention will next be described in the order of steps. FIGS. 1 to 3, FIG. 6 and FIG. 8 are fragmentary cross-sectional views of a semiconductor substrate illustrating the manufacturing method of shallow trench isolation; FIG. 4 is one example of a schematic view illustrating a high density plasma CVD apparatus; FIG. 5 is one example of a schematic view illustrating the CMP apparatus, and FIG. 7 is one example of a graph illustrating the relationship between a driving motor torque current of a polishing pad and a polishing time.

As illustrated in FIG. 1, a semiconductor substrate (wafer processed into a thin disc sheet) 1 made of single crystal silicon and having a specific resistance of, for example, from about 1 Ω-cm to 10 Ω-cm is prepared. The semiconductor substrate 1 is then thermally oxidized, for example, at about 850° C. to form a pad oxide film 2, for example, as thin as about 10 nm on the main surface of the substrate. A protection film, for example, a silicon nitride film 3 having a thickness of from about 100 nm to 200 nm is formed over the pad oxide film 2, for example, by CVD. This pad oxide film 2 is formed for the purpose of relaxing a stress to be applied to the semiconductor substrate 1 when an insulating film to be filled inside of the isolation trench is densified in a later step. The silicon nitride film 3 is not oxidized easily so that it is utilized as a mask for preventing the oxidation of the surface of the semiconductor substrate 1 below the silicon nitride film (active region).

As illustrated in FIG. 2, with a resist pattern formed by photolithography as a mask, the silicon nitride film 3 and pad oxide film 2, which are exposed therefrom, are removed by dry etching from the element isolation regions. After removal of the resist pattern, with a remaining portion of the silicon nitride film 3 as a mask, the semiconductor substrate 1 exposed therefrom is removed by dry etching, whereby a plurality of isolation trenches 4 having, for example, a depth of about 300 nm are formed in the element isolation region of the semiconductor substrate 1. In the semiconductor substrate 1, various isolation trenches 4 which are different in an aspect ratio (a ratio (=d/w) of depth d to width w) are formed. These isolation trenches 4 have an aspect ratio of from about 0.2 to 0.4 with 0.18 μm as the minimum width.

The semiconductor substrate 1 is then thermally oxidized at about 1000° C. to form a silicon oxide film 5 of thickness of about 10 nm on the inside wall of the isolation trench 4 in order to remove a damage layer which has appeared on the inside wall of the isolation trench 4 as a result of dry etching. A silicon oxynitride film can be formed further on the inside wall of the isolation trench 4 by the heat treatment in an atmosphere containing oxygen and nitrogen. In this case, a stress to be applied to the semiconductor substrate 1 when an insulating film to be filled inside of the isolation trench 4 is densified in the later step can be relaxed further. Instead of the above-described heat treatment in an atmosphere containing oxygen and nitrogen, the silicon nitride film may be formed by CVD. The latter method can bring about similar effects.

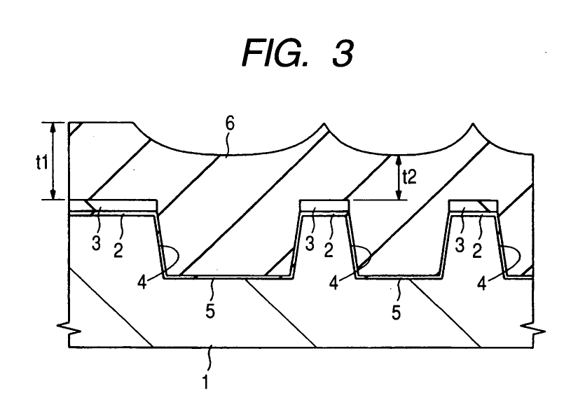

As illustrated in FIG. 3, an HDP film 6 is formed on the main surface of the semiconductor substrate 1 including the inside of the isolation trench 4 by high density plasma CVD using, for example, ICP (Inductively Coupled Plasma) as a plasma source. This HDP film 6 is thicker than a depth of the isolation trench 4 (for example, about 300 nm). On the surface of the silicon nitride film 3, an HDP film 6 having, for example, a thickness of from about 440 nm to 600 nm is formed. The term “thickness of the HDP film 6” as used herein means a thickness (thickness indicated by T1 in FIG. 3) from the surface of the silicon nitride film 3 to the highest surface of the HDP film 6.

The HDP film 6 is formed using a high density plasma CVD apparatus. FIG. 4 is one example of a schematic view illustrating the high density plasma CVD apparatus.

The pressure in a reaction chamber 7 of the high density plasma CVD apparatus M1 is maintained at a pressure as low as about 10 uPa by vacuum evacuation using TMP (Turbo Molecular Pump) 8 and DP (Diffusion Pump) 9, whereby the directivity of an active species toward a wafer (semiconductor substrate 1) SW from a plasma generation region 10 is made stronger than that of another CVD apparatus (for example, normal pressure CVD apparatus, reduced pressure CVD apparatus or plasma CVD apparatus). A raw material gas is converted into plasma by applying a source power (for example, frequency of from 300 kHz to 400 kHz) from a low frequency power source 11a to the reaction chamber 7 and sputter etching is conducted by applying a bias power (for example, frequency of from 13.56 MHz) from a high frequency power source 11b to the wafer SW. Deposition and sputter etching are thus carried out simultaneously, which enables filling of the HDP film 6 inside of the narrow isolation trench 4. Since an RF bias is applied to the wafer SW, the surface of the wafer SW is heated by collision energy of active species. The high density plasma CVD apparatus M1 therefore has a structure in which the wafer SW is closely attached onto an electrostatic chuck 12 and heat is removed by cooling with He from the backside of the wafer. Various gases such as process gas (SiH₄, He, O₂), passivation gas (H₂) and cleaning gas (NF₃) are fed into the reaction chamber 7 via gas nozzles 13a and 13b.

On the surface of the HDP film 6 formed by the high density plasma CVD, there exist protrusions having characteristic shapes formed by the simultaneous progress of deposition and sputter etching. After formation of the HDP film 6, these protrusions must therefore be removed by the CMP step. When a ratio of the thickness removed by sputter etching to the deposition thickness of the HDP film 6 (which will hereinafter be referred to as “a sputter etching/deposition ratio, simply) is smaller, the protrusions of the HDP film 6 become greater and as described above, the polishing time of the HDP film 6 in the CMP step becomes relatively longer. When a sputter etching/deposition ratio is greater, on the other hand, the silicon nitride film 3 tends to be removed more easily.

In the present invention, a sputter etching/deposition ratio falling within a range of from 0.12 to 0.22 is regarded appropriate. Adoption of this appropriate sputter etching/deposition ratio makes it possible to suppress sputter etching of the silicon nitride film 3, thereby forming an HDP film 6 having protrusions with a relatively reduced height. By relatively decreasing the height of the protrusions of the HDP film 6 in this manner, abrasive grains contained in the slurry efficiently act on polishing in the later CMP step, which leads to shortening of the polishing time of the HDP film 6.

A sputter etching/deposition ratio ranging from 0.12 to 0.22 can be attained, for example, under the following conditions. These film forming conditions are used for the high density plasma CVD apparatus M1 investigated by the present inventors for treating the wafer SW having a diameter of 300 nm. Each range is not limited to these specific numbers and it may exceed or fall below the specific numbers. It is needless to say that the film forming conditions are not limited to the below-described ranges and they vary, depending on the other parameters (for example, diameter of the wafer SW or aspect ratio of the isolation trench 4).

Flow rate of SiH₄: from 60 to 150 sccm

Flow rate of O₂: from 100 to 170 sccm

Flow rate of He: from 400 to 600 sccm

Source RF power: from 2500 to 4500 W

Bias RF power: from 3500 to 6000 W

The overfill thickness of the HDP film 6 when the sputter etching/deposition ratio falls within a range of from 0.12 to 0.22 is from about 10% to 20% of the depth of the isolation trench 4. The term “overfill thickness” as used herein means the thickness from the surface of the silicon nitride film 3 to the lowest surface of the HDP film 6 (thickness indicated by t2 in FIG. 3). In this embodiment, the HDP film 6 having an overfill thickness of from about 30 nm to 50 nm is formed relative to the isolation trench 4 having a depth of about 300 nm.

In order to improve the quality of the HDP film 6, the HDP film 6 is then densified by heat treating the semiconductor substrate 1. The resulting HDP film 6 is then polished by CMP with the silicon nitride film 3 as a stopper and left only inside of the isolation trench 4. An element isolation having a flattened surface is thus formed.

FIG. 5 is one example of a schematic view illustrating a CMP apparatus.

A CMP apparatus M2 has a turn table 14 on which a polishing pad 15 is rotatably disposed via a platen 16. The CMP apparatus M2 illustrated in FIG. 5 has only one polishing pad 15, but a plurality of, for example, three polishing pads may be disposed via respective rotatable platens. A load cup 17 for feeding and washing the wafer SW and transferring it to a polishing head which will be described later is disposed adjacent to the polishing pad 15. On the turn table 14, a slurry feed arm 18 for feeding the surface of the polishing pad 15 with a slurry and a deionized water feed arm 19 for feeding the surface of the polishing pad 15 with deionized water are disposed. A pad conditioner 20 for adjusting the surface condition of the polishing pad 15 is placed adjacent to the polishing pad 15.

A polishing head 23 is installed to the upper portion of the CMP apparatus M2 via a rotation shaft 22 extending in a vertical direction so that it comes opposite to the polishing pad 15. The polishing head 23 has a membrane which can be expanded or contracted by air supply and vacuuming. By such a mechanism, the wafer SW is maintained with its polished surface down and pressed against the polishing pad 15. The polishing head 23 has, on the upper portion thereof, a polishing head drive portion for rotating the rotation shaft 22 round an axis at a desired speed and oscillating it at a constant cycle. The polishing pad 15 has therebelow a polishing pad drive portion for rotating the platen 16 at a desired speed.

The HDP film 6 is polished, for example, by the below-described first and second polishing steps while using the CMP apparatus M2 having the above-described structure. The first polishing is conducted for selective polishing and removal of the protrusions from the HDP film 6 and it is followed by the second polishing conducted for polishing and removal of the remaining HDP film 6 outside the isolation trench 4 without impairing the flatness of its surface.

First, the wafer (semiconductor substrate 1) SW is supported, on the backside thereof (a surface opposite to a surface to be polished), by the polishing head 23 and the polishing head 23 is moved above the polishing pad 15 on the platen 16. The HDP film 6 with protrusions are formed, as illustrated in FIG. 3, on the outermost surface of the wafer SW having the isolation trench 4 formed therein. The polishing head 23 is then turned round the axis of the rotation shaft 22 and at the same time, oscillated in a horizontal direction. The polishing pad 15 is also turned with the platen 16. Without changing this state, the polishing pad 15 is brought into contact with the surface of the wafer SW to be polished (the surface on the side of the HDP film 6). First polishing of the HDP film 6 is started by feeding a slurry onto the polishing pad 15 at a constant flow rate.

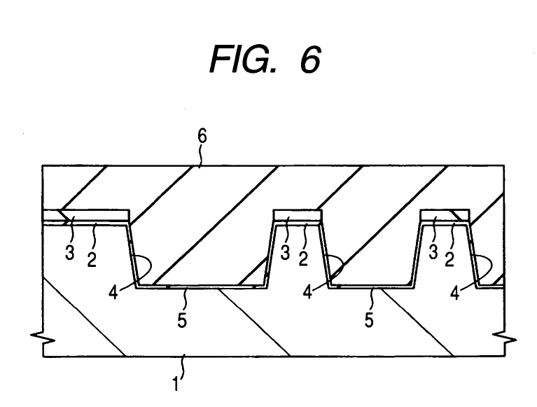

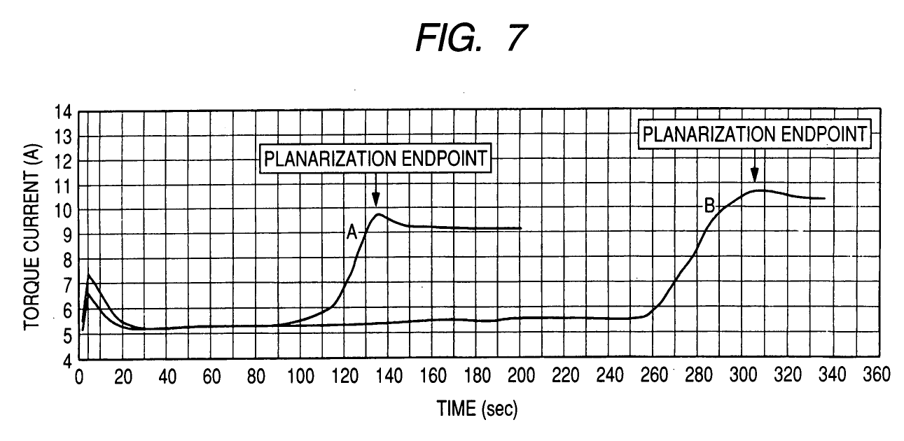

FIG. 6 is a fragmentary cross-sectional view of the semiconductor substrate after first polishing. An additive-containing ceria-based slurry having cerium oxide (CeO) particles as a main polishing component is used in the first polishing. The additive-containing ceria-based slurry is a self-stop type slurry and polishing of the HDP film 6 can be stopped when the surface of the HDP film 6 becomes almost flat.

The progress and end point of the first polishing for selectively polishing the protrusions of the HDP film 6 can be monitored, for example, by continuously measuring a torque current (a motor current at the polishing pad drive portion) of the polishing pad 15 of the CMP apparatus M2.

FIG. 7 is a graph illustrating one example of the relationship between the torque current of the polishing pad and a polishing time. In FIG. 7, both a torque current (A) of an HDP film with relatively small protrusions and a torque current (B) of an HDP film with relatively large protrusions are exemplified.

As soon as the first polishing of the HDP film 6 is started, the measurement of the torque current of the polishing pad 15 is also started. During the initiation of the polishing to the elimination of the protrusions from the HDP film 6, the torque current shows almost a constant value. As the protrusions of the HDP film 6 are eliminated, the torque current shows a gradual increase and it reaches the maximum value when the planarization of the surface of the HDP film 6 is substantially accomplished. Then the torque current again shows almost a constant value.

For example, assuming that the point at which the polishing pad 15 shows the maximum torque current is the end point of the first polishing, when this point is detected based on the judgment by a control portion of the CMP apparatus M2, an indication signal is output from the control portion to start the second polishing of the HDP film 6 following the first polishing.

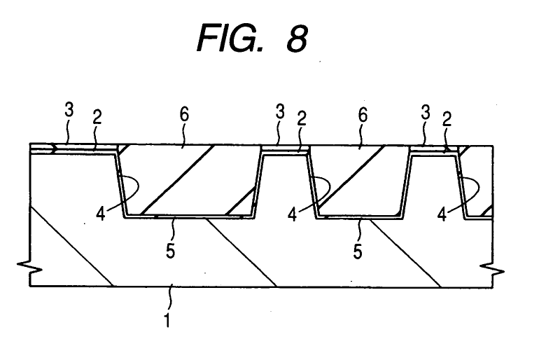

FIG. 8 is a fragmentary cross-sectional view illustrating the semiconductor substrate after second polishing. In the second polishing, without stopping the rotation of the polishing pad 15 and polishing head 23 and supply of the additive-containing ceria-based slurry in the first polishing, the additive-containing ceria-based slurry is diluted with deionized water fed onto the polishing pad 15, whereby a remaining portion of the HDP film 6 outside the isolation trench 4 is polished. The additive-containing ceria-based slurry and deionized water are each fed onto the polishing pad 15 at a constant flow rate. By diluting the additive-containing ceria-based slurry with deionized water, the HDP film 6 can be polished while maintaining the flatness of the surface of the HDP film 6. Moreover, by diluting the additive-containing ceria-based slurry with deionized water, a polishing rate selectivity of the HDP film 6 to the silicon nitride film 3 can be made relatively high. It is therefore possible to fill the HDP film 6 inside of the isolation trench 4 without leaving the HDP film 6 on the silicon nitride film 3.

As in the first polishing, the progress and end point of the second polishing for completely removing the HDP film 6 outside the isolation trench 4 can be monitored, for example, by continuously measuring the torque current of the polishing pad 15 of the CMP apparatus M2.

As soon as the second polishing of the HDP film 6 is started, the measurement of the torque current of the polishing pad 15 is started. During the time between the initiation of the polishing and the elimination of the HDP film 6 on the silicon nitride film 3, the rotation torque current shows almost a constant value. As the HDP film 6 on the surface of the silicon nitride film 3 is eliminated, the torque current shows a gradual increase and it reaches the maximum value when the HDP film 6 is completely removed from the surface of the silicon nitride film 3. Then the torque current again shows almost a constant value.

For example, assuming that the point at which the polishing pad 15 shows the maximum torque current is the end point of the second polishing, when this point is detected based on the judgment by the control portion of the CMP apparatus M2, an indication signal is output therefrom to stop the rotation of the polishing pad 15 and polishing head 23 and stop of the supply of the additive-containing ceria-based slurry and deionized water.

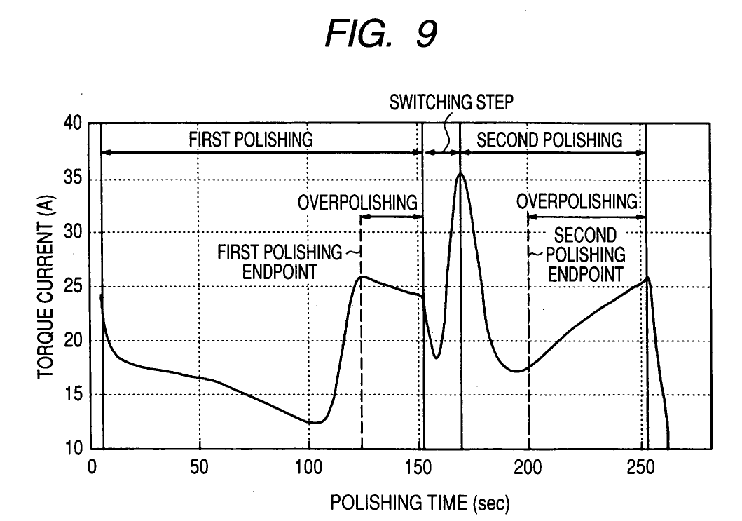

FIG. 9 illustrates one example of a time-dependent change of the torque current when the first polishing and second polishing are performed in succession. In this drawing, continuous treatment by the first polishing and second polishing including the overpolishing is shown. In the first polishing, the point at which the torque current shows the maximum value is determined as its end point. The first polishing is followed by the overpolishing and upon termination of the overpolishing, the first polishing is completed. In the overpolishing after the end point of the first polishing, the torque has a decreasing tendency. Then, the first polishing is switched to the second polishing. In the second polishing, the torque current shows a gradual decrease and reaches the minimum value. The point at which the torque current starts increasing from the minimum value is determined as the end point of the second polishing. The second polishing is followed by overpolishing. Upon termination of the overpolishing, the second polishing is completed. In the overpolishing after the second polishing, the torque current has an increasing tendency.

The wafer SW is then separated from the polishing pad 15 and moved above the polishing pad 15. The wafer SW carried out from the CMP apparatus M2 is washed and then, shallow trench isolation is formed thereover. Elements are then formed in active regions of the semiconductor substrate 1 partitioned by the shallow trench isolations.

In this Embodiment, in the second polishing for polishing the planarized HDP film 6, deionized water is fed onto the polishing pad 15 to dilute the additive-containing ceria-based slurry. The additive-containing ceria-based slurry can be diluted with not only deionized water but also a surfactant or the like fed onto the polishing pad 15.

In this embodiment, the second polishing is performed after the first polishing by supplying deionized water onto the polishing pad 15 without stopping the supply of the additive-containing ceria-based slurry. Dilution of the additive-containing ceria-based slurry is not limited to the above-described method, but various methods can be employed for it. For example, an additive-containing ceria-based slurry is prepared in advance and after the first polishing, the additive-containing ceria-based slurry diluted with water is fed onto the polishing pad 15 from the slurry feed arm 18 or a feed arm different therefrom. Or, supply of the additive-containing ceria-based slurry is terminated once after the first polishing and then, after complete removal of the additive-containing ceria-based slurry from the polishing pad 15, the diluted additive-containing ceria-based slurry may be fed onto the polishing pad 15.

As described above, according to the embodiment of the present invention, the height of the protrusions of the HDP film 6 deposited over the main surface of the semiconductor substrate 1 by the high density plasma CVD method can be made relatively low so that the polishing time of the HDP film in the CMP step can be reduced. In addition, in polishing of the HDP film 6 in the CMP step, the surface of the HDP film 6 is planarized by polishing it with the additive-containing ceria-based slurry (first polishing); without interruption, deionized water is fed onto the polishing pad 15 to dilute the additive-containing ceria-based slurry; and the HDP film 6 is polished until the exposure of the silicon nitride film 3 (second polishing). Without using an additive concentration regulator, feed lines for plural kinds of slurries or a plurality of polishing apparatuses, the concentration of the additive in the additive-containing ceria-based slurry can be changed easily and first polishing and second polishing can be conducted without interruption so that the polishing efficiency can be improved and the polishing time of the HDP film 6 in the CMP step can be shortened.

The invention made by the present inventors has so far been described specifically based on the above-described embodiment. It should however be borne in mind that the present invention is not limited to or by it, but can be changed without departing from the scope of the present invention.

For example, in the above-described embodiment, the invention is applied to the formation step of shallow trench isolation by filling a HDP film in an isolation trench, but can also be applied to the manufacturing method of any semiconductor device having a step of filling a recess with a film formed by the high density plasma CVD method.

The manufacturing method of the semiconductor device of the present invention can be applied to the manufacturing step of filling a recess with an HDP film.

What is claimed is:

1. A manufacturing method of a semiconductor device, comprising the steps of:
(a) forming a first insulating film over a main surface of a substrate;
(b) etching the first insulating film and the substrate successively to form a trench in the substrate;
(c) forming a second insulating film over the first insulating film including the inside of the trench by high density plasma CVD; and
(d) polishing the surface of the second insulating film by CMP to remove the second insulating film outside the trench,
wherein, in the step (c), a ratio of the thickness of the second insulating film to be sputter-etched to the thickness of the second insulating film to be deposited falls within a range of from 0.12 to 0.22.

2. A manufacturing method of a semiconductor device according to claim 1, wherein the thickness of the second insulating film formed in the step (c) extending from the surface of the first insulating film to a lowest surface of the second insulating film is from 10% to 20% of the depth of the trench.

3. A manufacturing method of a semiconductor device according to claim 1, wherein the second insulating film is made of an insulating film having silicon oxide as a main component and is formed under the following conditions: a SiH₄ flow rate ranging from 60 to 150 sccm, O₂ flow rate ranging from 100 to 170 sccm, He flow rate ranging from 400 to 600 sccm, source RF power ranging from 2500 to 4500 W and bias RF power ranging from 3500 to 6000 W.

4. A manufacturing method of a semiconductor device according to claim 1,
wherein the step (d) further comprises the steps of:
(e) polishing protrusions on the surface of the second insulating film; and
(f) subsequent to the step (e), polishing the surface of the second insulating film until the first insulating film is exposed, and
wherein, in the step (e), a time point when a torque current of a polishing pad increases and reaches the maximum value as a result of measurement of the torque current of the polishing pad is defined as a polishing end point of the step (e).

5. A manufacturing method of a semiconductor device according to claim 1,
wherein the step (d) further comprises the steps of:
(e) polishing protrusions on the surface of the second insulating film; and
(f) subsequent to the step (e), polishing the surface of the second insulating film until the first insulating film is exposed, and
wherein, in the step (f), a torque current of a polishing pad increases and reaches the maximum value as a result of measurement of the torque current of the polishing pad is defined as a polishing end point of the step (f).

6. A manufacturing method of a semiconductor device, comprising the steps of:
(a) forming a first insulating film over a main surface of a substrate;
(b) etching the first insulating film and substrate successively to form, in the substrate, a trench having an aspect ratio of from 0.2 to 0.4;
(c) forming a second insulating film over the first insulating film including the inside of the trench by high density plasma CVD; and
(d) polishing the surface of the second insulating film by CMP to remove the second insulating film outside the trench,
wherein, in the step (c), a ratio of the thickness of the second insulating film to be sputter-etched to the thickness of the second insulating film to be deposited falls within a range of from 0.12 to 0.22.

7. A manufacturing method of a semiconductor device according to claim 6, wherein the thickness of the second insulating film formed in the step (c) extending from the surface of the first insulating film to a lowest surface of the second insulating film is from 10% to 20% of the depth of the trench.

8. A manufacturing method of a semiconductor device according to claim 6, wherein the second insulating film is made of an insulating film having silicon oxide as a main component and is formed under the following conditions: a SiH₄ flow rate ranging from 60 to 150 sccm, O₂ flow rate ranging from 100 to 170 sccm, He flow rate ranging from 400 to 600 sccm, source power ranging from 2500 to 4500 W and bias power ranging from 3500 to 6000 W.

9. A manufacturing method of a semiconductor device according to claim 6,
wherein the step (d) further comprises the steps of:
(e) polishing protrusions on the surface of the second insulating film; and
(f) subsequent to the step (e), polishing the surface of the second insulating film until the first insulating film is exposed, and
wherein, in the step (e), a time point when a torque current of a polishing pad increases and reaches the maximum value as a result of measurement of the torque current of the polishing pad is defined as a polishing end point of the step (e).

10. A manufacturing method of a semiconductor device according to claim 6,
wherein the step (d) further comprises the steps of:
(e) polishing protrusions on the surface of the second insulating film; and
(f) subsequent to the step (e), polishing the surface of the second insulating film until the first insulating film is exposed, and
wherein, in the step (f), a time point when a torque current of a polishing pad increases and reaches the maximum value as a result of the measurement of the torque current of the polishing pad is defined as a polishing end point of the step (f).

11. A manufacturing method of a semiconductor device, comprising the steps of:
(a) forming a first insulating film over a main surface of a substrate;
(b) etching the first insulating film and the substrate successively to form a trench in the substrate;
(c) forming a second insulating film over the first insulating film including the inside of the trench by high density plasma CVD;
(d) polishing the protrusions on the surface of the second insulating film with a slurry by CMP; and
(e) subsequent to the step (d), until the first insulating film is exposed, polishing the surface of the second insulating film with the slurry which has been diluted while using CMP to remove the second insulating film outside the trench,
wherein, in the step (c), a ratio of the thickness of the second insulating film to be sputter-etched to the thickness of the second insulating film to be deposited falls within a range of from 0.12 to 0.22.

12. A manufacturing method of a semiconductor device according to claim 11, wherein the thickness of the second insulating film formed in the step (c) extending from the surface of the first insulating film to the lowest surface of the second insulating film is from 10% to 20% of the depth of the trench.

13. A manufacturing method of a semiconductor device according to claim 11, wherein the second insulating film is made of an insulating film having silicon oxide as a main component and is formed under the following conditions: a SiH₄ flow rate ranging from 60 to 150 sccm, O₂ flow rate ranging from 100 to 170 sccm, He flow rate ranging from 400 to 600 sccm, source power ranging from 2500 to 4500 W and bias power ranging from 3500 to 6000 W.

14. A manufacturing method of a semiconductor device according to claim 11, wherein a higher polishing rate selectivity to the second insulating film can be attained by the slurry which has been diluted than the slurry which has not been diluted.

15. A manufacturing method of a semiconductor device according to claim 14, wherein the slurry has cerium oxide as a main polishing component.

16. A manufacturing method of a semiconductor device according to claim 11, wherein in the step (e), a diluting solution is fed onto the substrate to dilute the slurry.

17. A manufacturing method of a semiconductor device according to claim 16, wherein the diluting solution is deionized water.

18. A manufacturing method of a semiconductor device according to claim 16, wherein the diluting solution is a surfactant.

19. A manufacturing method of a semiconductor device according to claim 11, wherein in the step (d), a time point when a torque current of a polishing pad increases and reaches the maximum value as a result of measurement of the torque current of the polishing pad is defined as a polishing end point in the step (d).

20. A manufacturing method of a semiconductor device according to claim 11, wherein in the step (e), a time point when a torque current of a polishing pad increases and reaches the maximum value as a result of measurement of the torque current of the polishing pad is defined as a polishing end point in the step (e).
